(19) United States
(12) Patent Application Publication
(10) Pub. No.: US 2026/0101830 A1
(43) Pub. Date: Apr. 9, 2026

(54) UV CURE TECHNOLOGY FOR BONDING FILM SURFACE ACTIVATION

(71) Applicant: Applied Materials, Inc., Santa Clara, CA (US)

(72) Inventors: Xinyi LU, Santa Clara, CA (US); Han WANG, Palo Alto, CA (US); Bo XIE, San Jose, CA (US); Monika Halim JAMIESON, Los Altos Hills, CA (US); Chi-I LANG, Cupertino, CA (US); Li-Qun XIA, Santa Clara, CA (US)

(21) Appl. No.: 19/347,187

(22) Filed: Oct. 1, 2025

Related U.S. Application Data
(60) Provisional application No. 63/705,375, filed on Oct. 9, 2024.

(51) Int. Cl. H01L 23/00

(52) U.S. Cl. CPC H10W 99/00; H10W 72/90; H10W 80/041; H10W 80/327; H10W 90/794

(57) ABSTRACT

Embodiments described herein generally relate to processes for back end of line advanced packaging assembly. More particularly, embodiments described herein relate to processes for activating silicon surfaces for hydrophilic silicon direct bonding applications. In at least one embodiment, a method for activating a substrate is provided. The method includes providing a substrate into a process chamber, the substrate including a plurality of patterned structures, at least one metal layer and a silicon surface, and curing the silicon surface of the substrate. The curing process includes flowing one or more gases into the process chamber, the one or more gases including ozone, and providing UV light while operating the process chamber at a temperature of about 25° C. to about 300° C. A plurality of oxygen radicals are formed from the ozone and reacted with the silicon surface of the substrate to form an activated surface.

### CROSS-REFERENCE TO RELATED APPLICATIONS

This application claims benefit of U.S. Provisional patent application Ser. No. 63/705,375, filed Oct. 9, 2024, which is herein incorporated by reference in its entirety.

### FIELD

Embodiments described herein generally relate to processes for semiconductor packaging. More specifically, embodiments described herein relate to processes for activating silicon surfaces for hydrophilic silicon direct bonding applications.

### BACKGROUND

Ongoing trends in the development of semiconductor device technology have led to semiconductor components having reduced sizes and increased circuit densities. In accordance with demands for continued scaling of semiconductor devices while improving performance capabilities, these components and circuits are integrated into complex 3D semiconductor device packages that facilitate a significant reduction in device footprint and enable shorter and faster connections between components. Such packages may integrate, for example, semiconductor chips and a plurality of other electronic components for mounting onto a circuit board of an electronic device.

Conventionally, semiconductor device packages have been fabricated on organic package substrates due to the ease in forming features and connections therein, as well as the relatively low package manufacturing costs associated with organic composites. However, as circuit densities are increased and semiconductor devices are further miniaturized, the utilization of organic package substrates becomes impractical due to limitations with the material structuring resolution needed to sustain device scaling and associated performance requirements.

More recently, 2.5D and/or 3D packages have been fabricated utilizing silicon-based substrates to compensate for some of the limitations associated with organic package substrates. Utilization of silicon-based materials for such packaging applications is driven by their excellent thermal properties, low coefficient of thermal expansion (CTE), smooth surfaces, and availability in large wafer and panel formats.

2.5D and/or 3D semiconductor device packages may be assembled using direct bonding. Direct bonding describes methods of joining two substrate surfaces at an atomic level, i.e., through chemical bonds between the substrates, without the use of intermediate layers, such as conductive adhesive layers, solders, etc., interposed there between. Direct bonding methods used in semiconductor device packages and other advanced packaging assemblies may be performed at temperatures below 450° C. in order to preserve the structures previously formed in the semiconductors. Due to the desired low thermal budget of direct bonding methods, there is a need to clean and activate the semiconductor surfaces before bonding.

Conventional methods for cleaning and activating silicon-based substrates for back end of line (BEOL) direct bonding include harsh plasma activation and wet chemical methods that can potently damage the near fully assembled semiconductor. Methods such as reactive clean (RCA) (e.g., a mixture of water (H₂O), hydrogen peroxide (H₂O₂), and ammonium hydroxide (NH₄OH) or a mixture of H₂O, H₂O₂, and hydrochloric acid (HCl)) and piranha solution (e.g., a mixture of sulfuric acid and H₂O₂) have been extensively investigated. Although the surface activation with wet chemical methods and plasma bombardment for hydrophilic silicon direct bonding have been widely used, high cost, high temperatures, and toxic chemical solutions still remain a challenge.

Thus, there is a need for low temperature, nontoxic silicon activation methods for back end of line advanced packaging assembly.

### SUMMARY

Embodiments described herein generally relate to processes for semiconductor packaging. More specifically, embodiments described herein relate to processes for activating silicon surfaces for hydrophilic silicon direct bonding applications.

In at least one embodiment, a method for activating a substrate is provided. The method includes, providing a substrate into a process chamber and curing the silicon surface of the substrate. The substrate includes a plurality of patterned structures, at least one metal layer, and a silicon surface. Curing the silicon surface of the substrate includes flowing one or more gases into the process chamber, the one or more gases including ozone, and providing UV light while operating the process chamber at a temperature of about 25° C. to about 300° C. The method further includes forming a plurality of oxygen radicals from the ozone and reacting the silicon surface of the substrate with the plurality of oxygen radicals to form an activated surface.

In at least one embodiment, a method for activating a substrate for direct bonding is provided. The method includes providing a substrate into a process chamber, the substrate being a back end of line (BEOL) semiconductor comprising a silicon surface. The method further includes, flowing one or more gases into the process chamber, providing UV light while operating the process chamber at a temperature of about 150° C. to about 250° C. and a pressure of about 6 Torr to about 25 Torr, and curing the silicon surface of the substrate to form an activated surface. The one or more gases including ozone.

In at least one embodiment, a method for direct bonding is provided. The method includes, providing a substrate into a process chamber and curing the silicon surface of the substrate. The substrate being a back end of line (BEOL) semiconductor comprising a silicon surface. Curing the silicon surface includes, flowing one or more gases into the process chamber, the one or more gases comprising ozone, providing UV light while operating the process chamber at a temperature of about 25° C. to about 300° C., and forming a plurality of oxygen radicals from the ozone. The method further includes, reacting the silicon surface of the substrate with the plurality of oxygen radicals to form an activated surface, and bonding the activated surface to a carrier substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a process chamber, according to one or more embodiments.

FIG. 2A is a depiction of a substrate, according to one or more embodiments.

FIG. 2B is a depiction of an activated substrate, according to one or more embodiments.

FIG. 2C is a depiction of a bonded substrate, according to one or more embodiments.

FIG. 3 is a flow diagram of a method for forming a semiconductor device package, according to one or more embodiments.

### DETAILED DESCRIPTION

Embodiments described herein generally relate to processes for semiconductor packaging, such as back end of line (BEOL) advanced packaging assembly. More particularly, embodiments described herein relate to processes for activating silicon (Si) surfaces for hydrophilic silicon direct bonding applications. It has been discovered that the surfaces of Si films disposed on BEOL semiconductor assemblies can be activated for hydrophilic silicon direct bonding applications using the ultraviolet (UV) ozone (O₃) curing methods described herein. Curing methods disclosed herein generally include exposing the Si film to O₃ and a UV light source at a temperature of less than about 300° C. Activation processes disclosed herein can elevate k values and increase surface hydrophilicity of the Si films.

At least some embodiments described herein implement a curing method that utilizes UV light and O₃ to activate the surfaces of Si films disposed on BEOL semiconductor assemblies. The activation results in an increase in silicon hydroxide on the surface of the silicon film, thus increasing the films k value and hydrophilicity. The increased hydrophilicity provides better efficiency for hydrophilic silicon direct bonding in later steps. The curing methods have the added benefit of also improving the surface roughness by removing the surface hydrocarbon contaminants, further increasing bonding efficiency in later steps. The dry curing methods and low thermal budget of the methods described herein ensure that the intricate features of the BEOL semiconductor assemblies are not lost or damaged during the surface activation process.

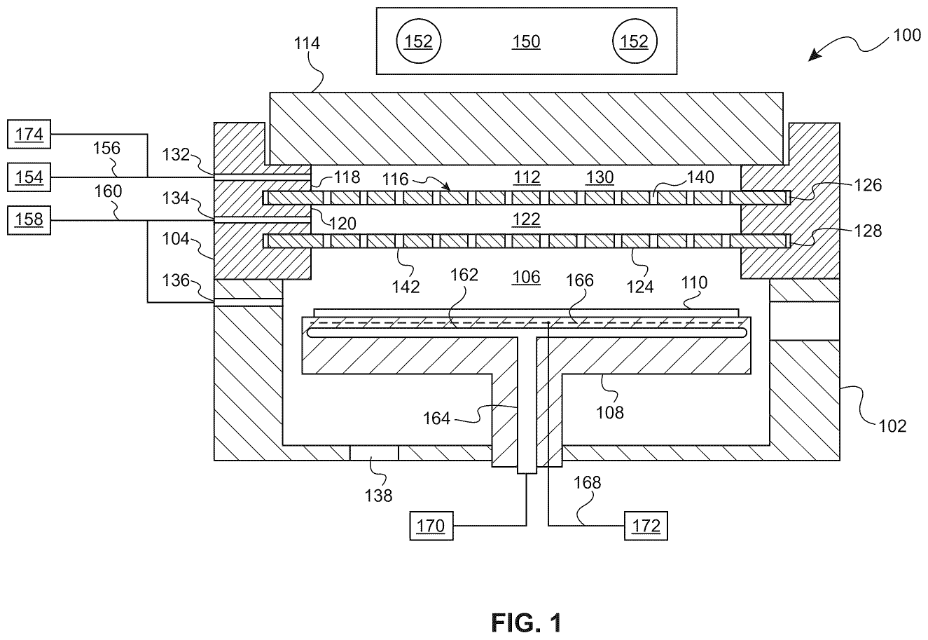

FIG. 1 is a schematic cross-sectional view of a process chamber 100, according to one or more embodiments. The process chamber 100 may be a vapor deposition chamber that includes UV radiation for assisting a silylation reaction. In one or more embodiments, the process chamber 100 may be the ONYX® or the SILENA® process chamber available from Applied Materials, Inc., of Santa Clara, California. The process chamber 100 may include a chamber body 102 and a chamber lid 104 disposed over the chamber body 102. The chamber body 102 and the chamber lid 104 may form an inner volume 106. A substrate support assembly 108 may be disposed in the inner volume 106. The substrate support assembly 108 may receive and support a substrate 110 thereon for processing.

A first UV transparent gas distribution showerhead 116 may be hung in the inner volume 106 through a central opening 112 of the chamber lid 104 by an upper clamping member 118 and a lower clamping member 120. The UV transparent glass distribution showerhead 116 may be positioned facing the substrate support assembly 108 to distribute one or more processing gases across a distribution volume 122 which is below the first UV transparent gas distribution showerhead 116. A second UV transparent showerhead 124 may be hung in the inner volume 106 through the central opening 112 of the chamber lid 104 below the first UV transparent gas distribution showerhead 116. Each of the UV transparent gas distribution showerheads 116, 124 may be disposed in a recess formed in the chamber lid 104. A first recess 126 may be an annular recess around an internal surface of the chamber lid 104, and the first UV transparent gas distribution showerhead 116 fits into the first recess 126. Likewise, a second recess 128 may receive the second UV transparent gas distribution showerhead 124.

A UV transparent window 114 may be disposed above the first UV transparent gas distribution showerhead 116. The UV transparent window 114 may be positioned above the first UV transparent gas distribution showerhead 116 forming a gas volume 130 between the UV transparent window 114 and the first UV transparent gas distribution showerhead 116. The UV transparent window 114 may be secured to the chamber lid 104 by any means, such as clamps, screws, bolts, etc.

The UV transparent window 114 and the first and second UV transparent gas distribution showerheads 116, 124 may be at least partially transparent to thermal or radiant energy within the UV wavelengths. The UV transparent window 114 may be quartz or another UV transparent material, such as sapphire, CaF₂, MgF₂, AlON, a silicon oxide material, a silicon oxynitride material, or another transparent material.

A UV source 150 may be disposed above the UV transparent window 114. The UV source 150 may be configured to generate UV energy and project the UV energy towards the substrate support assembly 108 through the UV transparent window 114, the first UV transparent gas distribution showerhead 116, and the second UV transparent gas distribution showerhead 124, thereby exposing the substrate 110 on the substrate support assembly 108 to UV light. A cover (not shown) may be disposed above the UV source 150. In one or more embodiments, the cover may be shaped to assist the projection of the UV energy from the UV source 150 towards the substrate support.

In one or more embodiments, the UV source 150 may include one or more UV lights 152 to generate UV radiation. The UV lights 152 may be lamps, LED emitters, or other UV emitters. In one or more embodiments, the UV lights 152 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, rare earth near-UV lamps such as europium-doped strontium borate or fluoroborate lamps discharging at 368-371 nm, to name a few examples.

The process chamber 100 may include flow channels 132, 134, 136 configured to supply one or more processing gases across the substrate support assembly 108 to process a substrate 110 disposed thereon. A first flow channel 132 provides a flow pathway for gas to enter the gas volume 130 and to be exposed to UV radiation from the UV source 150. The gas from the gas volume 130 may flow through the first UV transparent gas distribution showerhead 116 into the distribution volume 122. A second flow channel 134 may provide a flow pathway for precursor compounds and gases to enter the distribution volume 122 directly without passing through the first UV transparent gas distribution showerhead 116 to mix with the gas that was previously exposed to UV radiation in the gas volume 130. The mixed gases in the distribution volume 122 may be further exposed to UV radiation through the first UV transparent gas distribution showerhead 116 before flowing through the second UV transparent gas distribution showerhead 124 into a space proximate the substrate support assembly 108. The gas proximate the substrate support assembly 108, and a substrate disposed on the substrate support assembly 108, is further exposed to the UV radiation through the second UV transparent gas distribution showerhead 124. Purge gases may be provided through an opening 138 in the bottom of the process chamber 100 such that the purge gas flow around the substrate support assembly 108, preventing intrusion of processing gases into the space under the substrate support assembly 108. One or more gases may be exhausted through the opening 138.

The first UV transparent gas distribution showerhead 116 may include a plurality of holes 140 that allow processing gas to flow from the gas volume 130 to the distribution volume 122. The second UV transparent gas distribution showerhead 124 may also include a plurality of holes 142 that allow processing gas to flow from the distribution volume 122 into the processing space proximate the substrate support assembly 108. The holes 140, 142 in the first and second UV transparent gas distribution showerheads 116, 124 may be evenly distributed or irregularly spaced.

A purge gas or carrier gas source 154 may be coupled to the first flow channel 132 through a conduit 156. Purge gas from the purge gas source 154 may be provided through the first flow channel 132 during substrate processing to prevent intrusion of process gases into the gas volume 130. A cleaning gas source 174 may also be coupled to the first flow channel 132 through the conduit 156 to provide cleaning of the conduit 156, the first flow channel 132, the gas volume 130, and the rest of the process chamber 100 when not processing substrates.

A process gas or precursor compound source 158 may be coupled to the second flow channel 134 through a conduit 160 to provide a mixture, as described above, to the chamber body 102. The process gas source 158 may also be coupled to a third flow channel 136. Appropriate valves may allow selection of one or both of the flow channels 134, 136 for flowing the process gas mixture into the chamber body 102.

Substrate temperature may be controlled by providing heating and cooling features in the substrate support assembly 108. A coolant conduit 164 may be coupled to a coolant source 170 to provide a coolant to a cooling plenum 162 disposed in the substrate support assembly 108. One example of a coolant that may be used is a mixture of 50% ethylene glycol in water, by volume. The coolant flow is controlled to maintain temperature of the substrate at or below a desired level to promote deposition of UV-activated oligomers or fragments on the substrate. A heating element 166 may also be provided in the substrate support assembly 108. The heating element 166 may be a resistive heater, and may be coupled to a heating source 172, such as a power supply, by a conduit 168. The heating element 166 may be used to heat the substrate during a hardening process.

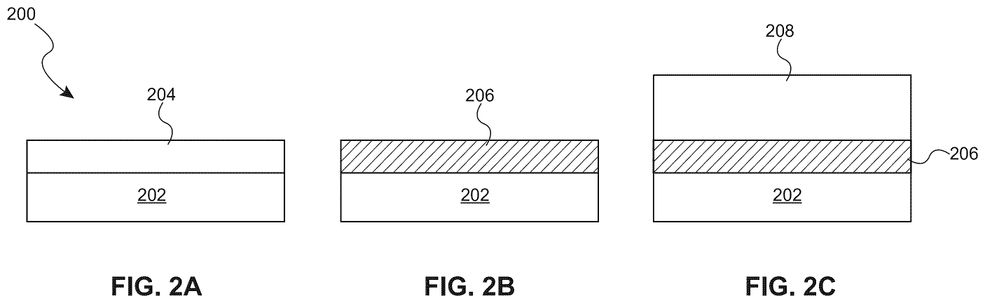

FIG. 2A is a depiction of a substrate 200, according to one or more embodiments. The substrate 200 includes a semiconductor 202, which may be a complete semiconductor or a nearly complete semiconductor, such as a BEOL semiconductor. A BEOL semiconductor includes a plurality of previously patterned structures and at least one metal layer. The semiconductor 202 may contain a plurality of previously patterned structures (not shown) that allow the underlying device to function; these structures may include but are not limited to, source/drain structures, channel structures, gate structures, metal wiring, through silicon vias (TSVs), metal interconnect structures, and combinations thereof. The structures of the semiconductor 202 may be formed from a plurality of materials having different coefficients of thermal expansion; these materials may include, but are not limited to, low-k materials, metal materials, patterning materials, and combinations thereof. A Si surface 204 is disposed on the semiconductor 202. The Si surface 204 may be a film, such as a silicon oxide film. In at least one embodiment, the Si surface 204 is a low-k dielectric Si film. Low-k dielectric Si films exhibit hydrophobic properties, which are unfavorable for wafer-level hydrophilic silicon direct bonding and thus need to be activated before bonding.

To facilitate hydrophilic silicon direct bonding, the Si surface 204 may be activated using the UV O₃ cure methods described herein. In various embodiments, surface preparation/activation is performed for the down-stream processes, as it facilitates the strong bonding needed for packaging processes. In some embodiments, which may be combined with other embodiments, the Si surface 204 is cured with O₃ and UV light to activate the upper portion of the Si surface 204, forming an activated Si film 206 depicted in FIG. 2B. The activated Si film 206 may have higher concentration of silicon hydroxide (SiOH) and a higher k than the Si surface 204. In at least some embodiments, the activated Si film 206 may have a k of about 2.9 to about 7.8, such as about 3.0 to about 7.5, about 3.0 to about 6.0, about 3.0 to about 5.0, or about 3.0 to about 4.0. In at least one embodiment the activated Si film 206 has a k of about 2.9 to about 4.8. In at least some embodiments, the k of the activated Si film 206 may have a percent increase of about 20% or greater when compared to the k of the Si surface 204. The percent increase may be about 20% or greater, such as about 30% or greater, about 40% or greater, about 50% or greater, about 100% or greater, about 200% or greater, or about 300% or greater. In at least some embodiments, the SiOH of the activated Si film 206 may have a percent increase of about 30% or greater when compared to the SiOH of the Si surface 204. The percent increase may be about 30% or greater, such as about 40% or greater, about 50% or greater, about 75% or greater, about 100% or greater, about 200% or greater, or about 300% or greater. During the cure, the UV light reacts with the O₃ to produce oxygen (O) radicals. The O radicals oxidize the upper portion of Si surface 204 to form SiOH, increasing the film's k and hydrophilicity. The O radicals also react with any surface hydrocarbon contaminants to form carbon monoxide, carbon dioxide, or combinations thereof. This reaction removes the surface hydrocarbon contaminants, improving the surface roughness.

In some embodiments, which can be combined with other embodiments, the activated Si film 206 may be bonded to a carrier substrate 208 using hydrophilic silicon direct bonding. In at least some embodiments, the carrier substrate 208 may be a wafer or a semiconductor chip.

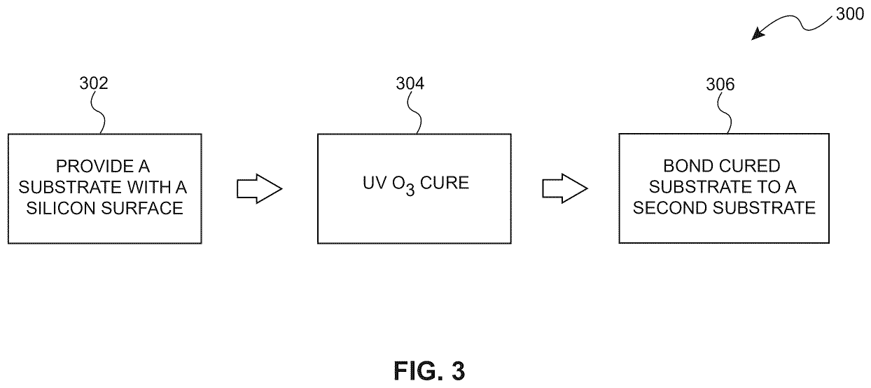

FIG. 3 is a flow diagram of a method 300 for forming a semiconductor device package, according to one or more embodiments. The method 300 may be performed in any suitable process chamber, such as the process chamber 100 depicted in FIG. 1.

Operation 302 includes providing a substrate into a process chamber. The substrate may be a BEOL semiconductor with a Si surface disposed thereon, such as substrate 200.

Operation 304 includes a UV O₃ cure. During operation 304, O₃ is flowed into the process chamber under UV light, and the process chamber is operated at a temperature of less than about 300° C. In some embodiments, the UV light may have a wavelength of about 100 nanometers (nm) to about 500 nm, such as about 100 nm to about 450 nm, about 200 nm to about 400 nm, about 100 nm to about 300 nm, or about 100 nm to about 200 nm. In at least one embodiment, which can be combined with other embodiments, the UV wavelength is about 200 nm to about 500 nm. At this wavelength, there is little to no molecular oxygen (O₂) UV absorption. However, when O₃ is exposed to the UV light, O₃ is efficiently dissociated into chemically active O radicals.

In some embodiments, O₃ may be introduced to the process chamber using a gas flow rate of about 1,000 standard cubic centimeters per minute (sccm) to about 10,000 sccm, such as about 2,000 sccm to about 9,000 sccm, such as about 2,000 sccm to about 7,000 sccm, alternatively about 1,000 sccm to about 5,000 sccm, about 2,000 sccm to about 5,500 sccm, about 3,500 sccm to about 5,000 sccm, or about 4,000 to about 10,000 sccm.

In some embodiments, O₃ may be introduced into the process chamber with additional carrier gases, such as helium (He), argon (Ar), or combinations thereof. In some embodiments, the flow rate ratio of O₃ to the carrier gas may be between about 10:1 to about 1:40, such as about 10:1 to about 1:20, about 1:10, about 1:2, about 1:4, about 5:1, about 1:5, about 1:30, or about 1:3. He may be introduced into the process chamber using a gas flow rate of about 1,000 sccm to about 20,000 sccm, such as about 2,000 sccm to about 18,000 sccm, about 4,000 sccm to about 16,000 sccm, alternatively about 1,000 sccm to about 10,000 sccm, about 10,000 sccm to about 20,000 sccm, about 5,000 sccm to about 15,000 sccm, or about 4,000 to about 5,000 sccm. Ar may be introduced into the process chamber using a gas flow rate of about 1,000 sccm to about 20,000 sccm, such as about 2,000 sccm to about 18,000 sccm, about 4,000 sccm to about 16,000 sccm, alternatively about 1,000 sccm to about 10,000 sccm, about 10,000 sccm to about 20,000 sccm, about 5,000 sccm to about 15,000 sccm, or about 4,000 to about 5,000 sccm. In some embodiments, He and Ar are provided simultaneously at equal flow rates. In other embodiments, He and Ar are provided at different flowrates.

In one or more embodiments, the pressure within the process chamber during operation 304 may be about 3 Torr to about 760 Torr, such as about 5 Torr to about 200 Torr, 5 Torr to about 100 Torr, about 6 Torr to about 25 Torr, alternatively about 3 Torr to about 600 Torr, about 500 Torr to about 760 Torr, about 50 Torr to about 500 Torr, or about 50 Torr to about 200 Torr. In one or more embodiments, the temperature within the process chamber during operation 304 may be about 25° C. to about 300° C., such as about 50° C. to about 250° C., 250° C. to about 300° C., alternatively about 25° C. to about 100° C., about 25° C. to about 200° C., about 75° C. to about 300° C., or about 150° C. to about 250° C. For example, in at least one embodiment, the UV ozone activation is performed at a temperature of about 20° C. to about 25° C. at atmospheric pressure, such as a pressure of about 760 Torr. In another embodiment, the UV ozone activation is performed at a temperature of about 100° C. to about 300° C. at atmospheric pressure, such as a pressure of about 760 Torr. In another embodiment, the UV ozone activation is performed at a temperature of about 20° C. to about 25° C. in vacuum ambient. In yet another embodiment, the UV ozone activation is performed at a temperature of about 100° C. to about 300° C. in vacuum ambient.

In one or more embodiments, the substrate may be exposed to the UV light and O₃ for about 1 min to about 20 min, such as about 5 min to about 15 min, about 5 min to about 10 min, alternatively about 10 min to about 20 min, about 2.5 min to about 4 min, about 15 min to about 20 min, or about 7 min to about 10 min. The UV O₃ cure time is configured to be long enough to saturate the top of the Si surface 204 with SiOH.

In at least one embodiment, the UV O₃ cure is performed by exposing the substrate to UV light while flowing O₃ at a flowrate of about 1,000 to about 10,000 sccm, He at a flowrate of about 1,000 to about 20,000 sccm, and Ar at a flowrate of about 1,000 to about 20,000 sccm into the process chamber. The process chamber is operated at a temperature of about 150° C. to about 250° C. and a pressure of about 6 Torr to about 25 Torr for about 1 min to about 20 min to form the cured substrate with an activated Si film.

Without being bound by theory, it is believed that longer UV O₃ cure times may reduce the overall assembly time of advanced packages, as the resultant activated Si film 206 is highly saturated with SiOH, which increases the efficiency of hydrophilic silicon direct bonding in subsequent steps. In at least some embodiments, longer UV O₃ cure times may be from about 5 min to about 60 min, such as about 10 min to about 60 min, about 15 min to about 50 min, about 20 min to about 40 min, or about 15 min to about 30 min. The increase in the Si films' SiOH concentration and k is dependent on the amount of O₃ supplied during the UV O₃ curing process. As a non-limiting example, in one embodiment, when a Si film, such as the Si surface 204, was cured for 540 seconds with UV light and an O₃ flow rate 1,000 sccm, the k of the Si film increased from 2.92 to 4.68. By contrast, when a Si film was cured for 540 seconds with UV light and an O₃ flow rate 2,000 sccm, the k of the Si film increased from 2.92 to 7.66.

Operation 306 includes bonding the cured substrate to a second substrate. In some embodiments, which can be combined with other embodiments, the two substrates are bonded using hydrophilic silicon direct bonding. The bonding operation may be performed at a temperature less than about 450° C. In some embodiments, the second substrate may be a carrier substrate, such as 208 depicted in FIG. 2C. In some embodiments, the second substrate may be a wafer or a semiconductor chip.

Overall, the present disclosure provides methods to activate Si surfaces of BEOL semiconductor assemblies for hydrophilic silicon direct bonding applications. Curing methods disclosed herein generally include exposing the Si film to O₃ and a UV light source at a temperature of less than about 300° C. to elevate k values and increase surface hydrophilicity of the Si films. The increased hydrophilicity provides better efficiency for hydrophilic silicon direct bonding in later steps. The curing method has the added benefit of also improving the surface roughness by removing the surface hydrocarbon contaminants.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method of activating a substrate, comprising:
providing a substrate into a process chamber, the substrate comprising a plurality of patterned structures, at least one metal layer, and a silicon surface;
curing the silicon surface of the substrate, wherein the curing comprises:
flowing one or more gases into the process chamber, the one or more gases comprising ozone;
providing UV light while operating the process chamber at a temperature of about 25° C. to about 300° C.;
forming a plurality of oxygen radicals from the ozone; and
reacting the silicon surface of the substrate with the plurality of oxygen radicals to form an activated surface.

2. The method of claim 1, wherein the UV light has a wavelength of about 200 nm to about 500 nm.

3. The method of claim 1, wherein the ozone is flowed into the process chamber at a flow rate of about 1,000 sccm to about 10,000 sccm.

4. The method of claim 1, wherein the silicon surface of the substrate is cured for about 1 minute to about 20 minutes.

5. The method of claim 1, wherein the process chamber is operated at a pressure of about 3 Torr to about 760 Torr while providing the UV light.

6. The method of claim 1, wherein the one or more gases further comprise helium, and the helium is flowed into the process chamber at a flow rate of about 1,000 sccm to about 20,000 sccm.

7. The method of claim 1, wherein the one or more gases further comprise argon, and the argon is flowed into the process chamber at a flow rate of about 1,000 sccm to about 20,000 sccm.

8. The method of claim 1, wherein the substrate comprises a plurality of materials disposed below the silicon surface, two or more of the materials of the plurality of materials having different coefficients of thermal expansion.

9. The method of claim 1, wherein the activated surface has a higher concentration of silicon hydroxide (SiOH) than the silicon surface.

10. The method of claim 1, wherein the activated surface has a higher k than the silicon surface.

11. A method of activating a substrate for direct bonding, comprising:
providing a substrate into a process chamber, the substrate being a back end of line (BEOL) semiconductor comprising a silicon surface;
flowing one or more gases into the process chamber, the one or more gases comprising ozone;
providing UV light while operating the process chamber at a temperature of about 150° C. to about 250° C. and a pressure of about 6 Torr to about 25 Torr; and
curing the silicon surface of the substrate to form an activated surface.

12. The method of claim 11, wherein the UV light has a wavelength of about 200 nm to about 500 nm.

13. The method of claim 11, wherein the ozone is flowed into the process chamber at a flow rate of about 1,000 sccm to about 10,000 sccm.

14. The method of claim 11, wherein the silicon surface of the substrate is cured for about 1 minute to about 20 minutes.

15. The method of claim 11, wherein the one or more gases further comprise helium, and the helium is flowed into the process chamber at a flow rate of about 1,000 sccm to about 20,000 sccm.

16. The method of claim 11, wherein the one or more gases further comprise argon, and the argon is flowed into the process chamber at a flow rate of about 1,000 sccm to about 20,000 sccm.

17. The method of claim 11, wherein the substrate comprises a plurality of materials disposed below the silicon surface, two or more of the materials of the plurality of materials having different coefficients of thermal expansion.

18. A method for direct bonding, comprising:
providing a substrate into a process chamber, the substrate being a back end of line (BEOL) semiconductor comprising a silicon surface;
curing the silicon surface, wherein the curing comprises:
flowing one or more gases into the process chamber, the one or more gases comprising ozone;
providing UV light while operating the process chamber at a temperature of about 25° C. to about 300° C.;
forming a plurality of oxygen radicals from the ozone;
reacting the silicon surface of the substrate with the plurality of oxygen radicals to form an activated surface; and
bonding the activated surface to a carrier substrate.

19. The method of claim 18, wherein the process chamber is operated at a temperature of about 150° C. to about 250° C. and a pressure of about 6 Torr to about 25 Torr while providing the UV light.

20. The method of claim 18, wherein the carrier substrate is a wafer.
